(19) United States
(12) Patent Application Publication
(10) Pub. No.: US 2026/0076201 A1
(43) Pub. Date: Mar. 12, 2026

(54) LID OR STIFFENER ATTACHMENT STRUCTURE WITH A HYBRID ADHESIVE

(71) Applicant: Intel Corporation, Santa Clara, CA (US)

(72) Inventors: Nrup Liljibhai BALAR, Chandler, AZ (US); Zheng REN, Chandler, AZ (US); Shaoyin GUO, Gilbert, AZ (US)

(21) Appl. No.: 18/830,397

(22) Filed: Sep. 10, 2024

(51) Int. Cl. H01L 23/00; C09J 163/00; C09J 183/04

(52) U.S. Cl. CPC H10W 42/121; C09J 163/00; C09J 183/04; H10W 76/60; H10W 90/724

(57) ABSTRACT

An embodiment may include an apparatus, that comprises a first substrate and an adhesive layer on the first substrate. In an embodiment, the adhesive layer comprises a first adhesive, where the first adhesive is a polymer that comprises silicon and oxygen, and a second adhesive, where the second adhesive is an epoxy. In an embodiment, the first adhesive is adjacent to the second adhesive. In an embodiment, the apparatus further comprises a second substrate coupled to the first substrate by the adhesive layer.

### BACKGROUND

The control of warpage and thermal dissipation of microelectronic packages pose a major challenge as the package form factor and computational power increase. High stress and/or warpage packages (e.g. large form factor packages) encounter large warpage due to a large die area-to-substrate area ratio. The bare die packages of these large form factor devices rely on the thick stiffeners and adhesives to control the warpage to enable suitable surface mount technology (SMT) yield. During the high temperature solder ball attach and surface mount process, the large difference between the pre- and post-stiffener attach warpage results in high adhesive stress. This results in the packages being prone to stiffener delamination through adhesive failures at the substrate or stiffener interface, or through cohesive failure within the adhesive layer.

### BRIEF DESCRIPTION OF THE DRAWINGS

FIG. 1A is a cross-sectional illustration of a package substrate with a stiffener attached to the package substrate by an adhesive layer, in accordance with an embodiment.

FIG. 1B is a plan view illustration of the package substrate in FIG. 1A, in accordance with an embodiment.

FIG. 2A is a cross-sectional illustration of an interface between a package substrate and a stiffener with a crack propagating through the adhesive layer, in accordance with an embodiment.

FIG. 2B is a cross-sectional illustration of an interface between a package substrate and a stiffener with a crack propagating through the adhesive layer and stopped by a low modulus pillar, in accordance with an embodiment.

FIG. 3A is a cross-sectional illustration of a package substrate and a stiffener that is coupled to the package substrate by a hybrid adhesive layer, in accordance with an embodiment.

FIG. 3B is a plan view illustration of the package substrate in FIG. 3A, in accordance with an embodiment.

FIG. 3C is a plan view illustration of a package substrate with a hybrid adhesive layer with low modulus pillars located proximate to corner regions of the package substrate, in accordance with an embodiment.

FIG. 3D is a plan view illustration of a package substrate with a hybrid adhesive layer with low modulus blocks located proximate to corner regions of the package substrate, in accordance with an embodiment.

FIG. 4A-4D are cross-sectional illustrations depicting a process for attaching a layer to a package substrate with a hybrid adhesive layer, in accordance with an embodiment.

FIG. 5A-5D are cross-sectional illustrations depicting a process for attaching a layer to a package substrate with a hybrid adhesive layer, in accordance with an embodiment.

FIG. 6A-6C are cross-sectional illustrations depicting the interface between a package substrate and a stiffener that passes through a pillar of the hybrid adhesive layer, in accordance with various embodiments.

FIG. 7 is a flow diagram of a process for attaching a layer to a package substrate with a hybrid adhesive layer, in accordance with an embodiment.

FIG. 8 is a cross-sectional illustration of an electronic system with a package substrate and a stiffener that are coupled together by a hybrid adhesive layer, in accordance with an embodiment.

FIG. 9 is a schematic of a computing device built in accordance with an embodiment.

### EMBODIMENTS OF THE PRESENT DISCLOSURE

Described herein are package architectures with a stiffener attached to a package substrate by a hybrid adhesive, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, larger form factor microelectronic packages are susceptible to warpage that negatively impacts subsequent surface mount technologies (SMTs). For example, extreme warpage may result in improper solder attachment (e.g., solder bridging, solder opens, etc.) between a die and the package substrate. Typically, the warpage is mitigated through the use of a stiffener that is mechanically coupled to the package substrate. In some cases, an integrated heat spreader (IHS), a lid, or the like may also be coupled to the substrate and the die complex directly or through a stiffener (multi-piece IHS). Generally, the portion of the stiffener that is coupled to the package substrate is a frame (with any suitable closed or open shape) that is provided proximate to an outer perimeter of the package substrate. The stiffener may include a high modulus material in order to improve the stiffness of the microelectronic package. For example, the stiffener may comprise a metallic material or the like.

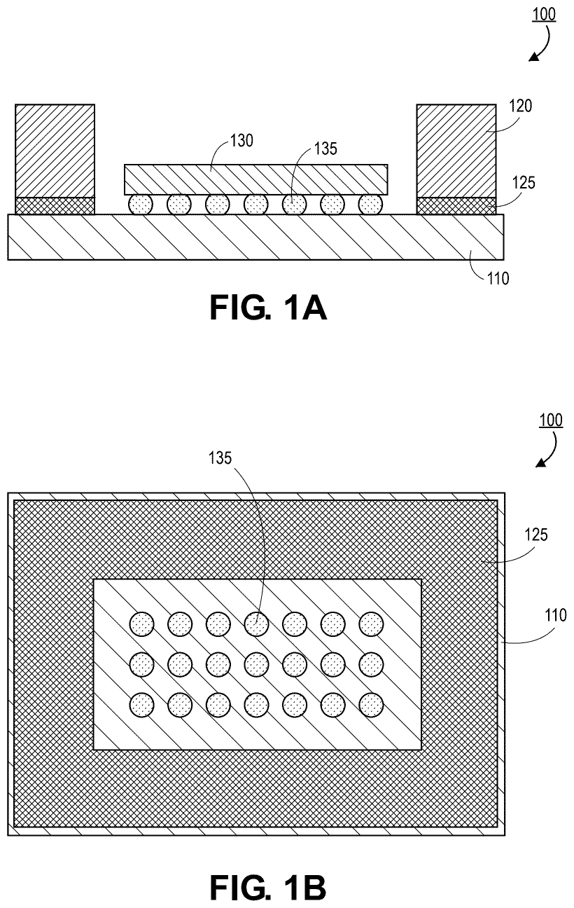

FIG. 1A is a cross-sectional illustration of such a microelectronic package 100. As shown, the microelectronic package 100 may comprise a package substrate 110. One or more dies 130 may be electrically coupled to the package substrate 110 by interconnects 135. The interconnects 135 may comprise any suitable first level interconnect (FLI) architecture, such as solder balls, hybrid bonds, and/or the like. A stiffener 120 coupled to the package substrate 110 may surround an outer perimeter of the one or more dies 130. The stiffener 120 may be mechanically coupled to the package substrate 110 by an adhesive layer 125. Typically, the adhesive layer is an epoxy material. Epoxy materials are generally used due to the high modulus that is obtained after the cure. The high modulus allows for good mechanical coupling in order to reduce warpage in the package substrate 110. However, as will be described in greater detail below, epoxy materials are susceptible to cracking and delamination.

FIG. 1B is a plan view illustration of the microelectronic package 100 in FIG. 1A. In FIG. 1B, the stiffener 120 and the die 130 are removed to more clearly illustrate the underlying features. As shown, the interconnects 135 may be arranged in an array, and the adhesive layer 125 forms a ring proximate to a perimeter of the package substrate 110. Adhesive layers 125 that are currently used comprise a uniform material composition. A uniform composition may not be beneficial for all applications. For example, the warpage of the package substrate 110 may result in uneven stress applied to the adhesive layer 125. High stress regions within the adhesive layer 125 can lead to cracking and/or delamination that negatively impacts the microelectronic package 100.

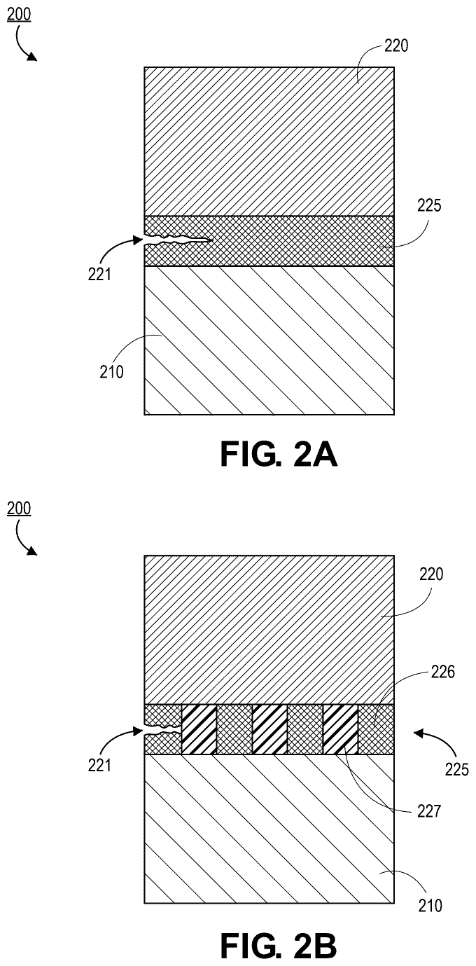

Referring now to FIG. 2A, a cross-sectional illustration of an interface between a package substrate 210 and a stiffener 220 of a microelectronic package 200 is shown. The package substrate 210 may be mechanically coupled to the stiffener 220 by an adhesive layer 225 that includes a high stiffness material, such as an epoxy adhesive material. Such high stiffness adhesive layers may suffer from being brittle. Accordingly, when stresses exceed a threshold value, a crack 221 may begin propagating through the adhesive layer 225. Since the entire adhesive layer 225 comprises the same epoxy material, there is no effective way to stop the propagation of the crack 221 through the adhesive layer 225. As such, the microelectronic package 200 may ultimately fail due to delamination, cracking, or the like. That is, failure of the adhesive layer 225 results in the stiffener 220 not being able to reduce the warpage in the package substrate 210 since the mechanical coupling is broken or rendered less effective.

Accordingly, embodiments disclosed herein comprise a hybrid adhesive layer between the package substrate and the stiffener (or other suitable substrate). In an embodiment, the hybrid adhesive layer may comprise a matrix material with a plurality of pillars distributed through the matrix material. In an embodiment, the matrix material may be a high modulus (e.g., high stiffness but with a low toughness) material, such as an epoxy, and the pillars may comprise a lower modulus (e.g., low stiffness but with a high toughness) material. The lower modulus material allows for an increase in the toughness of the adhesive layer. That is, the pillars are less likely to crack since they are less brittle. For example, the pillars may comprise a polymeric material that comprises silicon and oxygen (e.g., silicone). In some embodiments, any cracks that are initiated in the matrix material may be suppressed when the crack encounters one of the tough pillars. This prevents delamination and improves the overall robustness of the microelectronic package. Further, by retaining the high modulus matrix material in the hybrid adhesive layer, the mechanical coupling between the stiffener and the package substrate remains high so that the desired warpage reduction is still achieved. Additionally, the hybrid adhesive layer may provide benefits with respect to controlling the bond line thickness (BLT), which may be beneficial for assembly processes.

In an embodiment, the hybrid adhesive may have low modulus pillars distributed evenly throughout the matrix material. In other embodiments, the pillars may be located in regions of the matrix material that are expected to experience high stresses. For example, the pillars may be located in corner regions of the microelectronic package. In other embodiments, the pillars may be block-like structures. For example, a block of silicone may be provided proximate to the corners or other high stress locations of the microelectronic package. In certain embodiments, the hybrid adhesive material may be selectively deposited to control warpage in at risk areas of the microelectronic package. As such, the overall microelectronic package warpage can be more effectively controlled in order to meet certain warpage requirements of the microelectronic package.

Referring now to FIG. 2B, a cross-sectional illustration of a portion of a microelectronic package 200 that shows the interface between the package substrate 210 and a stiffener 220 is shown, in accordance with an embodiment. As shown, a hybrid adhesive layer 225 is provided between the package substrate 210 and the stiffener 220. The hybrid adhesive layer 225 may comprise a first adhesive material, which may be referred to as a matrix material 226, and a second adhesive material, which may be referred to as a pillar 227. In an embodiment, the pillars 227 may be discrete regions of the second adhesive material that are surrounded by the matrix material 226. In some instances, the pillars 227 may have a height that is substantially equal to the height of the matrix material 226. Though, in other embodiments, the pillars 227 may have heights that are smaller than the height of the matrix material 226.

In the illustrated embodiment, the pillars 227 have substantially vertical sidewalls. Though, it is to be appreciated that the pillars 227 may have any suitable sidewall profile, such as a curved sidewall profile. For example, different assembly and/or manufacturing processes may result in pillars 227 that have different cross-sectional profiles, as will be described in greater detail below.

In an embodiment, the matrix material 226 may have a modulus (e.g., an elastic modulus) that is higher than a modulus (e.g., an elastic modulus) of the pillars 227. The lower modulus of the pillars 227 may result in a higher toughness that is more effective at stopping the propagation of cracks. In some embodiments, the matrix material 226 may comprise an epoxy material, and the pillars 227 may comprise a polymeric material that comprises silicon and oxygen (e.g., silicone).

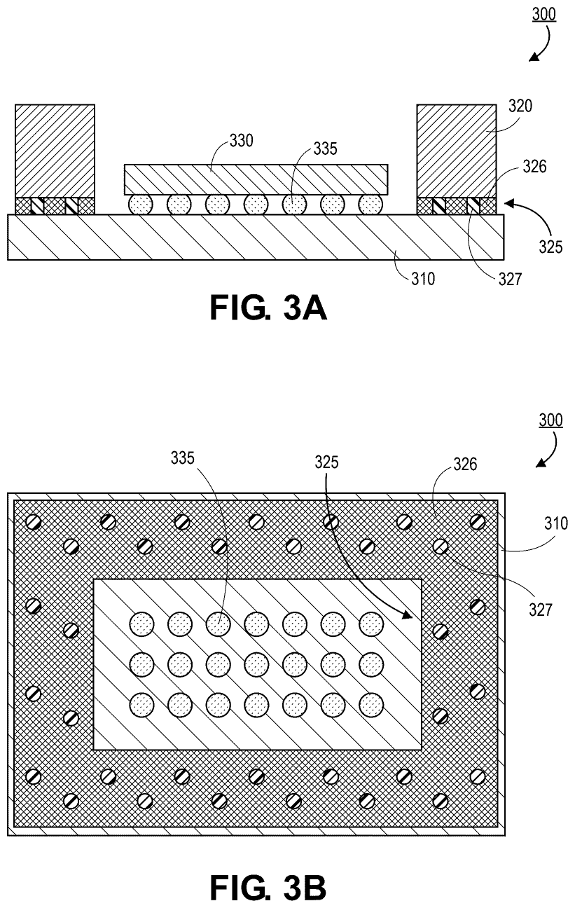

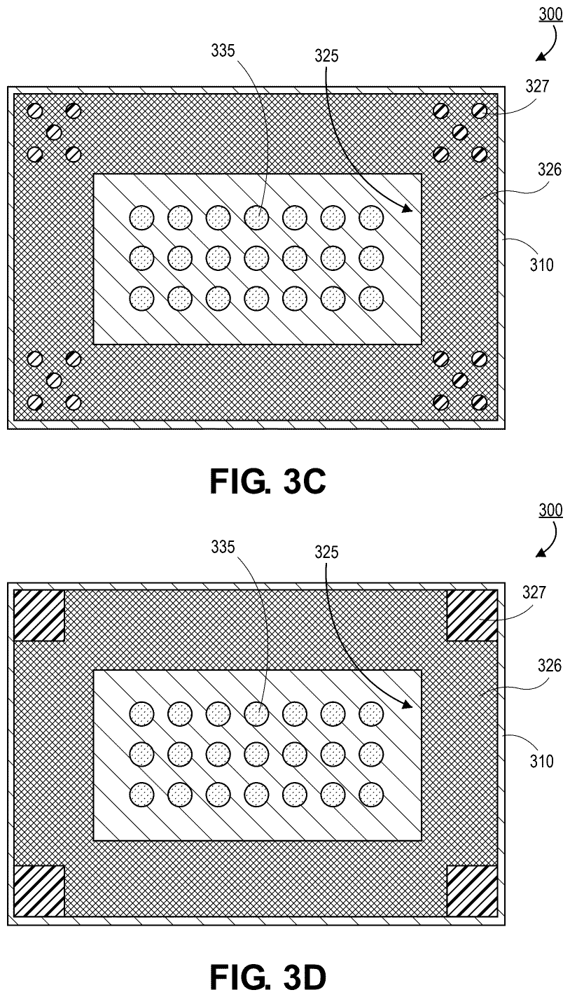

Referring now to FIG. 3A, a cross-sectional illustration of a microelectronic package 300 is shown, in accordance with an embodiment. In an embodiment, the microelectronic package 300 may comprise a package substrate 310. The package substrate 310 may include a plurality of laminated dielectric layers with electrical routing (not shown) embedded in one or more of the dielectric layers. For example, the dielectric layers may comprise an organic buildup film or the like. In some embodiments, the package substrate 310 may comprise a core (e.g., an organic core, a glass core, or the like). The package substrate 310 may sometimes be referred to simply as a substrate. It is to be appreciated that embodiments disclosed herein may include package substrates 310 suitable for any type of microelectronic package 300 architecture.

In an embodiment, one or more dies 330 may be electrically coupled to the package substrate 310. For example, the die 330 may be electrically coupled to the package substrate 310 by interconnects 335. The interconnects 335 may include solder balls, hybrid bonding interconnects, or any other suitable FLI architecture. In an embodiment, the one or more dies 330 may include any suitable type of die, such as a processor (e.g., a central processing unit (CPU), a graphics processing unit (GPU), an XPU, etc.) a memory die, a communications die, or any other type semiconductor based structure with one or more active components (e.g., transistors).

In an embodiment, a stiffener 320 may be provided over the package substrate 310. The stiffener 320 may refer to any type of substrate (or substrates) that are mechanically coupled to the package substrate 310. While referred to herein as a “stiffener”, the stiffener 320 may also be replaced with an IHS, a lid, or the like. More generally, the stiffener 320 or any suitable alternatives may comprise a material that has a stiffness (e.g., elastic modulus) that is higher and/or has a different coefficient of thermal expansion (CTE) than that of the package substrate 310. Accordingly, mechanically coupling the package substrate 310 to the stiffener 320 allows for the stiffener 320 to reduce warpage of the package substrate 310.

In an embodiment, the stiffener 320 may be a ring that surrounds a perimeter of the one or more dies 330. For example, the stiffener 320 may have an outer edge that is proximate to an edge of the package substrate 310. An inner edge of the stiffener 320 may be spaced away from the one or more dies 330. While the stiffener 320 is shown as a monolithic structure in FIG. 3A, it is to be appreciated that the stiffener 320 may comprise any number of layers, components, structures, etc., and the stiffener 320 may have any suitable shape that helps with warpage mitigation of the package substrate 310.

In an embodiment, the stiffener 320 may be mechanically coupled to the package substrate 310 by a hybrid adhesive layer 325. The hybrid adhesive layer 325 may comprise a matrix material 326 and a plurality of pillars 327 embedded within the matrix material 326. The matrix material 326 may have an elastic modulus that is higher than an elastic modulus of the pillars 327. Accordingly, the matrix material 326 may provide better stress transfer between the stiffener 320 and the package substrate 310, but the pillars 327 improve the overall toughness of the hybrid adhesive layer 325. As such, the hybrid adhesive layer 325 is less prone to cracking, delamination, and/or other damage. In a particular embodiment, the matrix material 326 comprises an epoxy and the pillars 327 comprise a polymer with silicon and oxygen (e.g., silicone).

Referring now to FIG. 3B, a plan view illustration of a portion of the microelectronic package 300 in FIG. 3A is shown, in accordance with an embodiment. In FIG. 3B the stiffener 320 and the die 330 are removed in order to more clearly illustrate the underlying structures. As shown, the plurality of pillars 327 are distributed throughout the matrix material 326. In the particular embodiment shown in FIG. 3B, the pillars 327 are arranged in a pair of rings. Though, it is to be appreciated that the pillars 327 may have any suitable distribution within the matrix material 326. For example, the pillars 327 may be distributed with a substantially uniform spacing throughout the entire matrix material 326. In FIG. 3B, each of the pillars 327 are substantially uniform with respect to shape and size. However, it is to be appreciated that the pillars 327 may have any suitable size or shape in order to provide the desired performance for the hybrid adhesive layer 325. For example, instead of circles, the pillars 327 may have rectangular shapes (when viewed from above) or any other shape.

Referring now to FIG. 3C, a plan view illustration of a portion of a microelectronic package 300 is shown, in accordance with an additional embodiment. As shown in FIG. 3C, the pillars 327 are concentrated at corner regions of the package substrate 310. The placement of pillars 327 proximate to the corner regions may be done to improve performance of the hybrid adhesive layer 325. For example, the stress in the hybrid adhesive layer 325 may be highest at the corner regions. As such, an increased density of tough pillars 327 may improve crack mitigation. The remaining portion of the hybrid adhesive layer 325 may be lower stress and crack propagation is not as big of a concern. Accordingly, these lower stress regions may comprise the matrix material 326 only in order to improve mechanical coupling between the package substrate 310 and the stiffener 320. More generally, the design and placement of pillars 327 in the hybrid adhesive layer 325 may strike a balance between strong mechanical coupling and toughness. A high volume percentage of the matrix material will provide good mechanical coupling but may result in a brittle adhesive layer. A high volume percentage of the pillars (i.e., a low modulus material) will result in a tougher (e.g., more crack and damage resistant) adhesive layer, but may not provide the desired mechanical coupling strength between the package substrate 310 and the stiffener 320.

Referring now to FIG. 3D, a plan view illustration of a microelectronics package 300 is shown, in accordance with yet another embodiment. The microelectronics package 300 in FIG. 3D may be similar to the microelectronics package 300 in FIG. 3C, with the exception of the structure of the pillars 327. Instead of a plurality of smaller pillars 327 in each corner region, a single pillar 327 that is a larger block is provided at each corner region. In some embodiments, portions of one or more of the pillars 327 may not be covered by the matrix material 326. That is, some portion of the pillars 327 may be exposed at an edge of the hybrid adhesive layer 325 in some embodiments.

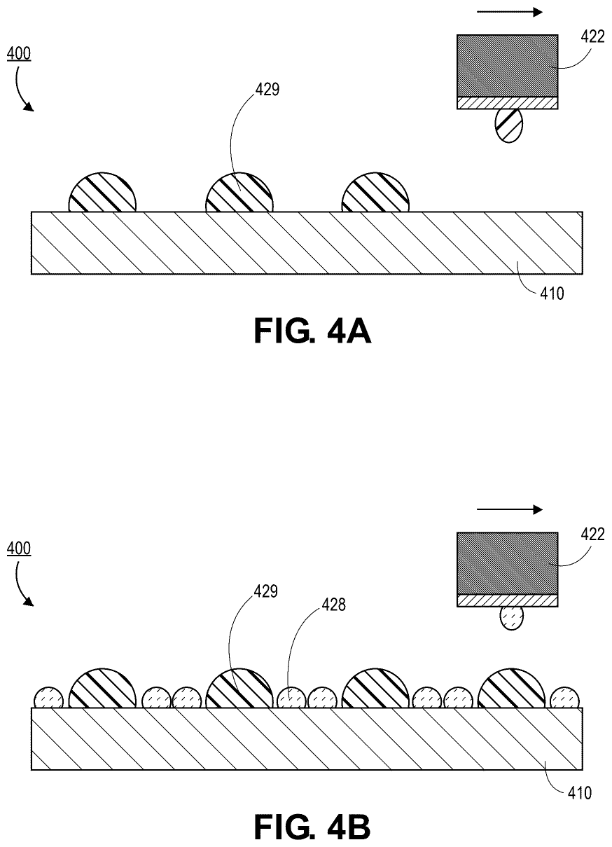

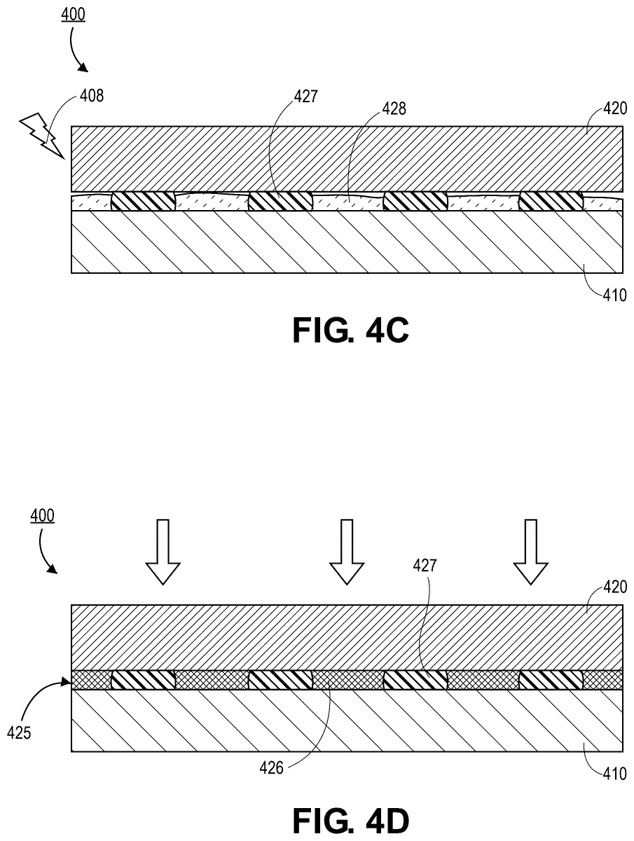

Referring now to FIG. 4A-4D, a series of cross-sectional illustrations depicting a process for forming a microelectronic package 400 with a hybrid adhesive layer 425 between the package substrate 410 and the stiffener 420 is shown, in accordance with an embodiment. In an embodiment, the hybrid adhesive layer 425 is deposited with at least two different deposition processes: 1) a jet dispense of a pillar material; and 2) a jet dispense of the matrix material.

Referring now to FIG. 4A, a cross-sectional illustration of a portion of a microelectronic package 400 at a stage of manufacture is shown, in accordance with an embodiment. In an embodiment, the microelectronic package 400 may comprise a package substrate 410. The package substrate 410 may be similar to any of the package substrates described in greater detail herein. For example, the package substrate 410 may comprise a plurality of laminated buildup layers with embedded electrical routing (not shown in FIG. 4A).

In an embodiment, a plurality of pillars 429 are dispensed onto a surface of the package substrate 410 with a dispensing process, such as a jet dispensing process. For example, a dispensing unit 422 may cross over the package substrate 410 laterally (as indicated by the arrow) in order to deposit pillars 429 across the surface of the package substrate 410. In an embodiment, the pillars 429 may be an adhesive material that is tougher than the regularly used adhesive materials, such as epoxy. For example, the pillars 429 may comprise a polymer, such as one comprising silicon and oxygen (e.g., silicone).

Referring now to FIG. 4B, a cross-sectional illustration of the portion of the microelectronic package 400 after drops 428 of a second adhesive material are deposited over the surface of the package substrate 410 is shown, in accordance with an embodiment. The drops 428 may be deposited with a dispensing process, such as a jet dispensing process. The second adhesive material may comprise an adhesive that has a higher elastic modulus (after curing) than the material for the pillars 429. For example, the drops 428 may comprise an uncured epoxy material. In the illustrated embodiment, the drops 428 are shown as being discrete drops that are each spaced apart from each other. Though, in some instances two or more of the drops 428 may be merged together.

Referring now to FIG. 4C, a cross-sectional illustration of the portion of the microelectronic package 400 after the stiffener 420 is attached to the package substrate 410 is shown, in accordance with an embodiment. In an embodiment, the stiffener 420 may be similar to any of the stiffeners, IHSs, or lids described in greater detail herein. The stiffener 420 may press down against the dots of pillars 429. Additionally, a curing operation 408 may be implemented in order to cure the pillars 429 to produce the cured pillars 427. The curing operation 408 may include an ultraviolet (UV) cure, a thermal cure (e.g., a differential thermal cure), or the like. The pillars 429 and drops 428 may be cured in two different operations or at the same curing operation. Curing the pillars before the thermal bonding operation may help control the BLT of the adhesive.

Referring now to FIG. 4D, a cross-sectional illustration of the microelectronic package 400 after a thermal bonding process (as indicated by the arrows) is implemented is shown, in accordance with an embodiment. In an embodiment, the thermal bonding process may include pressing the stiffener 420 against the package substrate 410. The thermal energy may also cure the drops 428 in order to produce a cured matrix material 426. The combination of the matrix material 426 and the pillars 427 may be considered a hybrid adhesive layer 425 in some embodiments. As shown, the matrix material 426 may surround the pillars 427 so that one or more of the pillars 427 are substantially embedded within the matrix material 426. For example, the matrix material 426 may directly contact sidewalls of the pillars 427 and surround perimeters of the pillars 427.

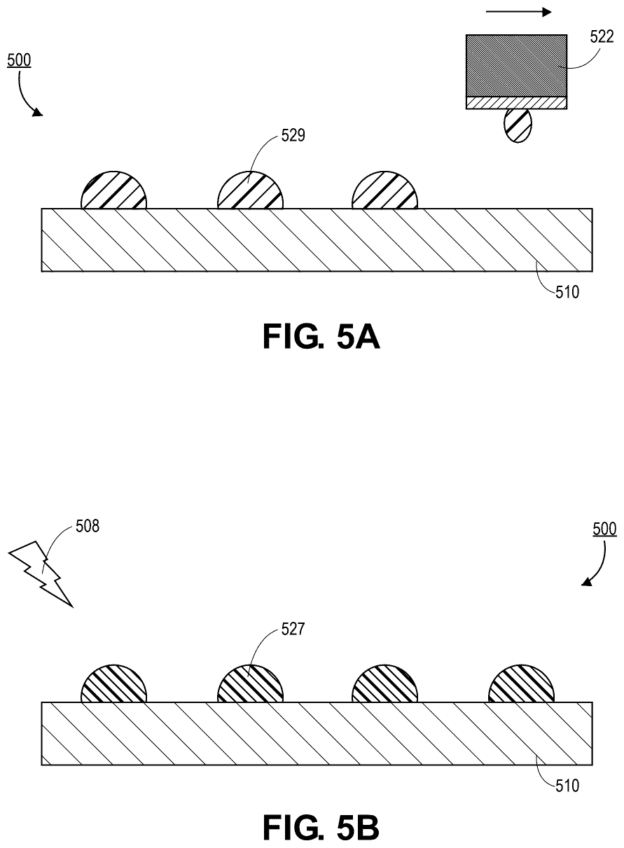

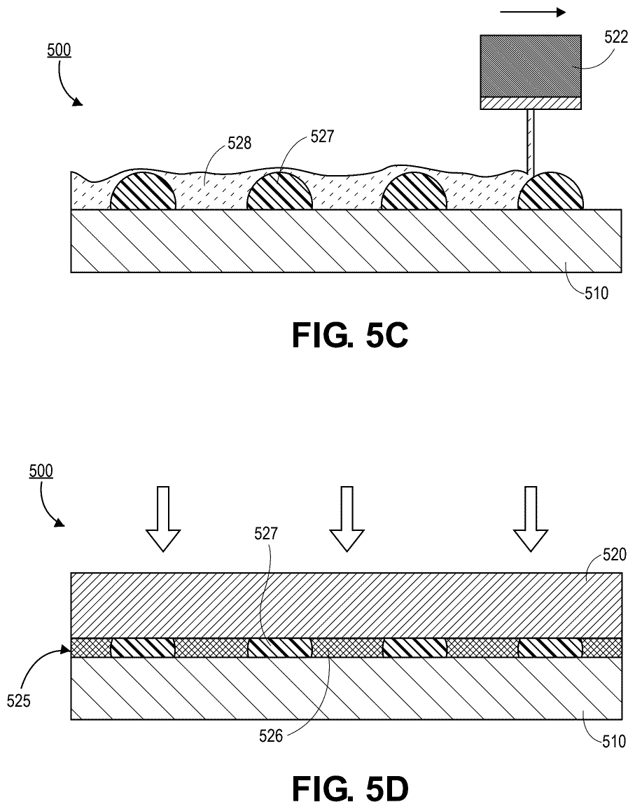

Referring now to FIG. 5A-5D a series of cross-sectional illustrations depicting a process for forming a microelectronic package 500 with a hybrid adhesion layer 525 between a package substrate 510 and a stiffener 520 is shown, in accordance with an embodiment. In an embodiment, the hybrid adhesive layer 525 is deposited with at least two different deposition processes: 1) a jet dispense of a pillar material; and 2) an auger dispense of the matrix material.

Referring now to FIG. 5A, a cross-sectional illustration of a portion of a microelectronic package 500 at a stage of manufacture is shown, in accordance with an embodiment. In an embodiment, the microelectronic package 500 may comprise a package substrate 510. The package substrate 510 may be similar to any of the package substrates described in greater detail herein. For example, the package substrate 510 may comprise a plurality of laminated buildup layers with embedded electrical routing (not shown in FIG. 5A).

In an embodiment, a plurality of pillars 529 are dispensed onto a surface of the package substrate 510 with a dispensing process, such as a jet dispensing process, an auger dispense process, or any other suitable dispensing process. For example, a dispensing unit 522 may cross over the package substrate 510 laterally (as indicated by the arrow) in order to deposit pillars 529 across the surface of the package substrate 510. In an embodiment, the pillars 529 may be an adhesive material that is tougher than the regularly used adhesive materials, such as epoxy. For example, the pillars 529 may comprise a polymer, such as one comprising silicon and oxygen (e.g., silicone).

Referring now to FIG. 5B, a cross-sectional illustration of the portion of the microelectronic package 500 after a curing operation 508 is shown, in accordance with an embodiment. In an embodiment, the curing operation 508 may be implemented in order to cure the pillars 529 to produce the cured pillars 527. The curing operation 508 may include a UV cure, a thermal cure, or the like.

Referring now to FIG. 5C, a cross-sectional illustration of the portion of the microelectronic package 500 after a matrix material 528 is deposited over the surface of the package substrate 510 is shown, in accordance with an embodiment. The matrix material 528 may be deposited with a continuous dispensing process, such as an auger dispensing process, using a dispensing unit 522. The matrix material 528 may comprise an adhesive that has a higher elastic modulus (when cured) than the material for the pillars 527. For example, the matrix material 528 may comprise an uncured epoxy material. In the illustrated embodiment, the matrix material 528 is dispensed to a height that covers the entirety of the pillars 527. Though, in some instances the matrix material 528 may be dispensed to a height that is equal to or less than the height of the pillars 527.

Referring now to FIG. 5D, a cross-sectional illustration of the portion of the microelectronic package 500 after the stiffener 520 is attached to the package substrate 510 is shown, in accordance with an embodiment. In an embodiment, the stiffener 520 may be similar to any of the stiffeners, IHSs, or lids described in greater detail herein. The stiffener 520 may press down against the pillars 527. In an embodiment, the stiffener 520 is attached with a thermal bonding process (as indicated by the arrows). In an embodiment, the thermal bonding process may include pressing the stiffener 520 against the package substrate 510. The thermal energy may also cure the matrix material 528 in order to produce a cured matrix material 526. The combination of the matrix material 526 and the pillars 527 may be considered a hybrid adhesion layer 525 in some embodiments. As shown, the matrix material 526 may surround the pillars 527 so that one or more of the pillars 527 are substantially embedded within the matrix material 526. For example, the matrix material 526 may directly contact sidewalls of the pillars 527 and surround perimeters of the pillars 527.

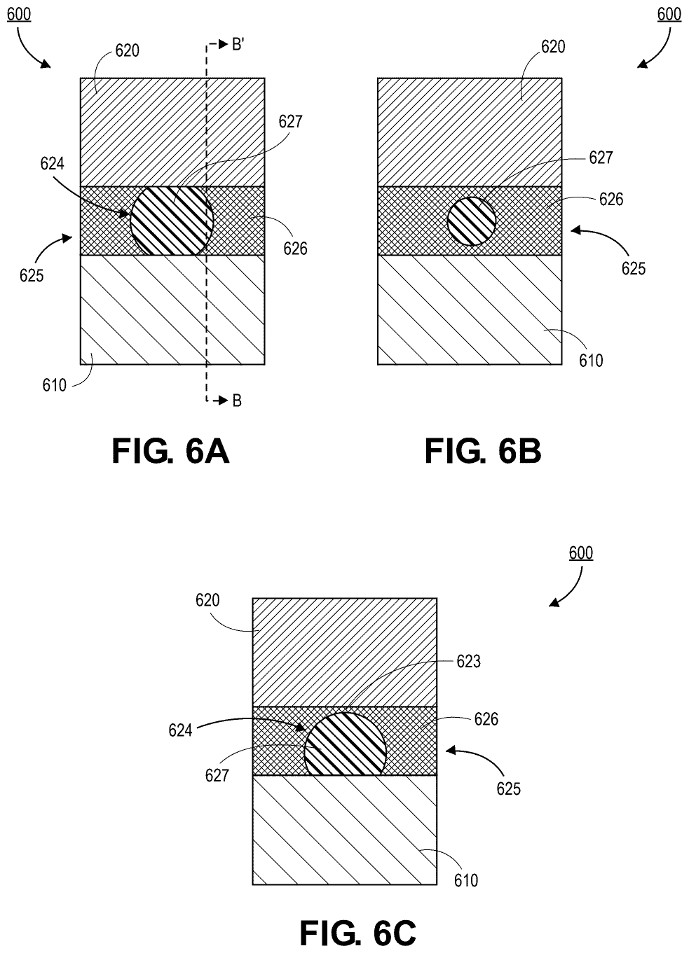

Referring now to FIG. 6A-6C, a series of cross-sectional illustrations depicting views of a portion of a microelectronic package 600 that shows an individual pillar 627 surrounded by the matrix material 626 between the package substrate 610 and the stiffener 620 is shown, in accordance with an embodiment.

In FIG. 6A, the plane of the cross-sectional view passes through a center of the pillar 627 within the hybrid adhesive layer 625. As shown, the pillar 627 extends from the package substrate 610 to the stiffener 620. That is, the pillar 627 may directly contact both the package substrate 610 and the stiffener 620. The matrix material 626 contacts an entire sidewall surface 624 of the pillar 627. In the illustrated embodiment, the sidewall surface 624 of the pillar 627 is curved. Though, the profile of the sidewall surface 624 may be substantially linear (e.g., vertical or sloped) or any other profile.

Referring now to FIG. 6B, a cross-sectional illustration of a portion of the microelectronic package 600 along line B-B′ in FIG. 6A is shown, in accordance with an embodiment. As shown, the pillar 627 does not contact the package substrate 610 or the stiffener 620. This may be due to the plane of the cross-section being taken off-center from the pillar 627. As such, there may be portions of the matrix material 626 between a top of the pillar 627 and the stiffener 620 as well as a portion of the matrix material 626 between the bottom of the pillar 627 and the package substrate 610.

Referring now to FIG. 6C, a cross-sectional illustration of a portion of a microelectronic package 600 is shown, in accordance with an additional embodiment. As shown, the pillar 627 contacts the package substrate 610, but the pillar 627 is spaced away from the stiffener 620. For example, a portion 623 of the matrix material 626 may be provided between a top of the pillar 627 and the stiffener 620. Such an embodiment may be provided when a continuous dispense process (e.g., an auger dispense process) is used to dispense the matrix material 626 over the pillar 627.

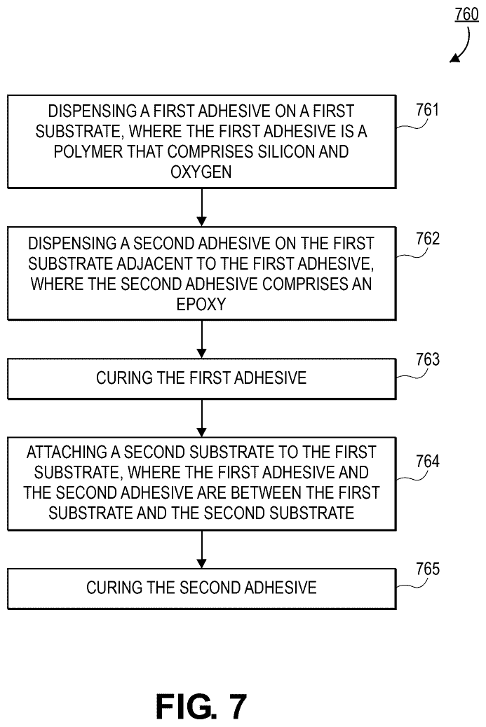

Referring now to FIG. 7, a flow diagram depicting a process 760 for forming a microelectronic package with a hybrid adhesive layer is shown, in accordance with an embodiment. In an embodiment, the microelectronic package formed with process 760 may be similar to any of the microelectronic packages described in greater detail herein.

In an embodiment, the process 760 may begin with operation 761, which comprises dispensing a first adhesive on a first substrate. In an embodiment, the first adhesive is a polymer that comprises silicon and oxygen. The first adhesive may be dispensed as a plurality of pillars across the surface of the first substrate. The first substrate may be a package substrate or the like. In an embodiment, the first adhesive may be dispensed with a jetting process.

In an embodiment, the process 760 may continue with operation 762, which comprises dispensing a second adhesive on the first substrate adjacent to the first adhesive. In an embodiment, the second adhesive comprises an epoxy. The second adhesive may also be dispensed with a jet dispensing technique in order to provide drops of the second adhesive on the first substrate. In another embodiment, the second adhesive may be dispensed with a continuous dispensing technique, such as an auger dispensing process. In a continuous dispensing process, the second adhesive may also be provided over a top of the first adhesive.

In an embodiment, the process 760 may continue with operation 763, which comprises curing the first adhesive. The first adhesive may be cured with a UV curing process, a thermal process, or the like.

In an embodiment, the process 760 may continue with operation 764, which comprises attaching a second substrate to the first substrate. In an embodiment, the first adhesive and the second adhesive are between the first substrate and the second substrate. In some embodiments, the second substrate may comprise a stiffener, an IHS, a lid, or the like.

In an embodiment, the process 760 may continue with operation 765, which comprises curing the second adhesive. The curing process for the second adhesive may comprise a thermal treatment. For example, the attachment of the second substrate may be a thermal bonding process that also cures the second adhesive. In an embodiment, the combination of the first adhesive and the second adhesive may sometimes be referred to as a hybrid adhesive layer.

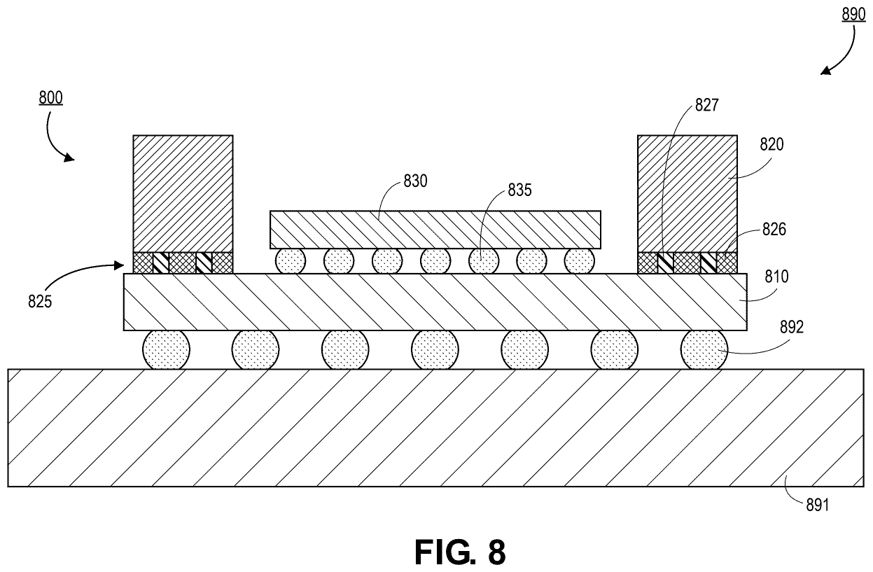

Referring now to FIG. 8, a cross-sectional illustration of an electronic system 890 is shown, in accordance with an embodiment. In an embodiment, the electronic system 890 may comprise a board 891, such as a printed circuit board (PCB), a motherboard, or the like. In an embodiment, a microelectronic package 800 is coupled to the board 891 by interconnects 892. The interconnects 892 may be any suitable second level interconnect (SLI), such as solder bumps, sockets, or the like.

In an embodiment, the microelectronic package 800 may be similar to any of the microelectronic packages described in greater detail herein. For example, the microelectronic package 800 may comprise a package substrate 810 with one or more dies 830 coupled to the package substrate 810 by interconnects 835. The interconnects 835 may be any suitable FLI, such as solder balls, copper bumps, hybrid bonding interconnects, or the like. The one or more dies 830 may be any type of die, such as those described in greater detail herein.

In an embodiment, a stiffener 820 (or a lid, an IHS, or the like) may be mechanically coupled to the package substrate 810 in order to mitigate warpage in the microelectronic package 800. The stiffener 820 may be mechanically coupled to the package substrate 810 by a hybrid adhesive layer 825. The hybrid adhesive layer 825 may comprise a matrix material 826 and a plurality of pillars 827. The matrix material 826 may have a higher modulus than the pillars 827. For example, the matrix material 826 may comprise an epoxy and the pillars 827 may comprise silicone. The matrix material 826 provides strong mechanical coupling, and the pillars 827 increase the toughness of the hybrid adhesive layer 825 in order to mitigate cracking, delamination, and/or the like. In an embodiment, the hybrid adhesive layer 825 may be similar to any of the hybrid adhesive layers described in greater detail herein.

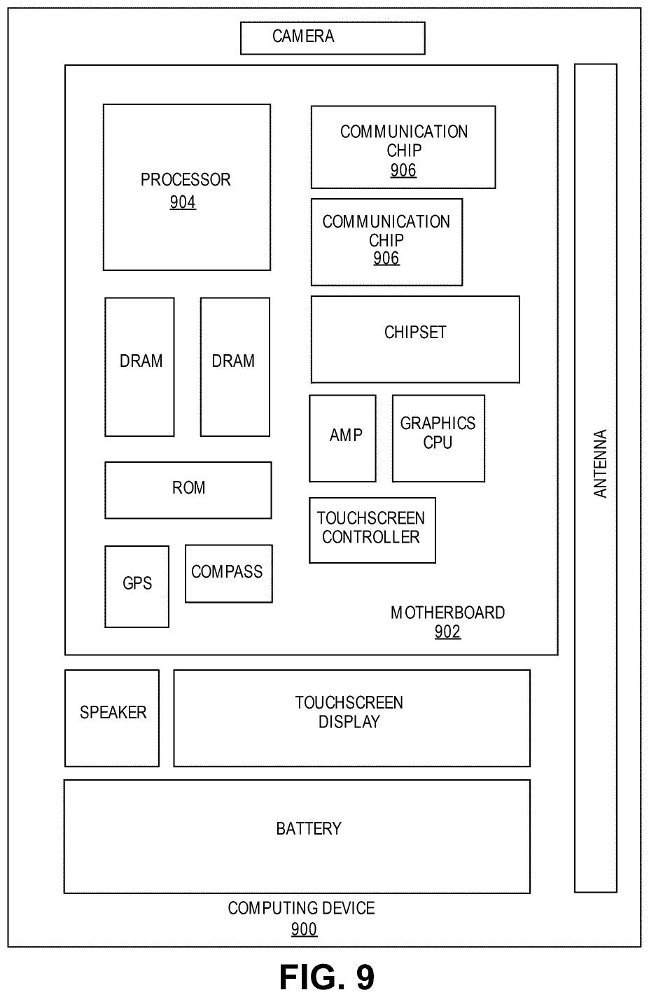

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that comprises a stiffener or the like that is mechanically coupled to a package substrate by a hybrid adhesive layer that comprises an epoxy matrix material and a plurality of pillars that comprise silicone, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that comprises a stiffener or the like that is mechanically coupled to a package substrate by a hybrid adhesive layer that comprises an epoxy matrix material and a plurality of pillars that comprise silicone, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a first substrate; an adhesive layer on the first substrate, wherein the adhesive layer comprises: a first adhesive, wherein the first adhesive is a polymer that comprises silicon and oxygen; and a second adhesive, wherein the second adhesive is an epoxy, and wherein the first adhesive is adjacent to the second adhesive; and a second substrate coupled to the first substrate by the adhesive layer.

Example 2: the apparatus of Example 1, wherein a sidewall of the first adhesive is covered by the second adhesive.

Example 3: the apparatus of Example 1 or Example 2, wherein a perimeter of the first adhesive is surrounded by the second adhesive.

Example 4: the apparatus of Examples 1-3, wherein a height of the first adhesive is substantially equal to a height of the second adhesive.

Example 5: the apparatus of Examples 1-4, wherein a portion of the second adhesive is provided between the first adhesive and the second substrate.

Example 6: the apparatus of Examples 1-5, wherein a sidewall of the first adhesive is curved.

Example 7: the apparatus of Examples 1-6, wherein the first adhesive comprises a plurality of pillars, and wherein each of the plurality of pillars are surrounded by the second adhesive.

Example 8: the apparatus of Examples 1-7, wherein the first substrate is a package substrate, and wherein the second substrate is a stiffener, an integrated heat spreader (IHS), or a lid.

Example 9: the apparatus of Example 8, wherein the second substrate is a ring, and wherein a die is coupled to the package substrate within an opening of the ring.

Example 10: the apparatus of Example 9, wherein the package substrate is coupled to a board.

Example 11: an apparatus, comprising: a package substrate; a die coupled to the package substrate; and a frame coupled to the package substrate by a hybrid adhesive layer, wherein the hybrid adhesive layer comprises: a plurality of pillars, wherein the plurality of pillars comprise a first material composition; and a matrix that surrounds the plurality of pillars, wherein the matrix comprises a second material composition that is different than the first material composition.

Example 12: the apparatus of Example 11, wherein the first material composition comprises silicon and oxygen.

Example 13: the apparatus of Example 11 or Example 12, wherein the second material composition comprises an epoxy.

Example 14: the apparatus of Examples 11-13, wherein the plurality of pillars are distributed around a perimeter of the die.

Example 15: the apparatus of Examples 11-14, wherein the plurality of pillars are positioned proximate to corners of the frame.

Example 16: the apparatus of Examples 11-15, wherein the plurality of pillars contact the package substrate and the frame.

Example 17: the apparatus of Examples 11-16, wherein a portion of the matrix is between one or more of the plurality of pillars and the frame.

Example 18: an apparatus, comprising: a package substrate; a layer coupled to the package substrate by an adhesive, and wherein the adhesive comprises: an epoxy matrix; and a plurality of silicone structures embedded in the epoxy matrix.

Example 19: the apparatus of Example 18, wherein the plurality of silicone structures have curved sidewalls.

Example 20: the apparatus of Example 18 or Example 19, wherein the layer is a stiffener comprising a metallic material.

What is claimed is:

1. An apparatus, comprising:
a first substrate;
an adhesive layer on the first substrate, wherein the adhesive layer comprises:
a first adhesive, wherein the first adhesive is a polymer that comprises silicon and oxygen; and
a second adhesive, wherein the second adhesive is an epoxy, and wherein the first adhesive is adjacent to the second adhesive; and
a second substrate coupled to the first substrate by the adhesive layer.

2. The apparatus of claim 1, wherein a sidewall of the first adhesive is covered by the second adhesive.

3. The apparatus of claim 1, wherein a perimeter of the first adhesive is surrounded by the second adhesive.

4. The apparatus of claim 1, wherein a height of the first adhesive is substantially equal to a height of the second adhesive.

5. The apparatus of claim 1, wherein a portion of the second adhesive is provided between the first adhesive and the second substrate.

6. The apparatus of claim 1, wherein a sidewall of the first adhesive is curved.

7. The apparatus of claim 1, wherein the first adhesive comprises a plurality of pillars, and wherein each of the plurality of pillars are surrounded by the second adhesive.

8. The apparatus of claim 1, wherein the first substrate is a package substrate, and wherein the second substrate is a stiffener, an integrated heat spreader (IHS), or a lid.

9. The apparatus of claim 8, wherein the second substrate is a ring, and wherein a die is coupled to the package substrate within an opening of the ring.

10. The apparatus of claim 9, wherein the package substrate is coupled to a board.

11. An apparatus, comprising:
a package substrate;
a die coupled to the package substrate; and
a frame coupled to the package substrate by a hybrid adhesive layer, wherein the hybrid adhesive layer comprises:
a plurality of pillars, wherein the plurality of pillars comprise a first material composition; and
a matrix that surrounds the plurality of pillars, wherein the matrix comprises a second material composition that is different than the first material composition.

12. The apparatus of claim 11, wherein the first material composition comprises silicon and oxygen.

13. The apparatus of claim 11, wherein the second material composition comprises an epoxy.

14. The apparatus of claim 11, wherein the plurality of pillars are distributed around a perimeter of the die.

15. The apparatus of claim 11, wherein the plurality of pillars are positioned proximate to corners of the frame.

16. The apparatus of claim 11, wherein the plurality of pillars contact the package substrate and the frame.

17. The apparatus of claim 11, wherein a portion of the matrix is between one or more of the plurality of pillars and the frame.

18. An apparatus, comprising:
a package substrate;
a layer coupled to the package substrate by an adhesive, and wherein the adhesive comprises:
an epoxy matrix; and
a plurality of silicone structures embedded in the epoxy matrix.

19. The apparatus of claim 18, wherein the plurality of silicone structures have curved sidewalls.

20. The apparatus of claim 18, wherein the layer is a stiffener comprising a metallic material.
